(19) United States
(12) Patent Application Publication
(10) Pub. No.: US 2011/0284078 A1
(43) Pub. Date: Nov. 24, 2011

(54) METHOD OF FORMING CADMIUM TELLURIDE THIN FILM

(75) Inventor: Bulent M. BASOL, Manhattan Beach, CA (US)

(73) Assignee: EncoreSolar, Inc., Fremont, CA (US)

(21) Appl. No.: 13/109,837

(22) Filed: May 17, 2011

Related U.S. Application Data
(60) Provisional application No. 61/396,114, filed on May 21, 2010.

(51) Int. Cl. H01L 21/36; H01L 31/0296

(52) U.S. Cl. 136/260; 438/478; 257/E21.461

(57) ABSTRACT

A method of forming a metal telluride (MTe) film on a base where M is Cd and optionally additionally may include at least one of Zn, Hg, Mn and Mg, involves depositing a Te-rich precursor layer on a base and reaction of the Te-rich precursor layer with an M-containing material at elevated temperature. The Te-rich precursor film is one of a MTex compound film with an x value larger than 1, a composite film comprising MTe and Te, and a composite film comprising a MTex compound film with an x value larger than 1. In a preferred embodiment the Te-rich precursor layer is electrodeposited. In another preferred embodiment both the Te-rich precursor layer and the M-containing material are electrodeposited. In yet another preferred embodiment the Te-rich precursor film is one of a CdTex compound film with an x value larger than 1, a composite film comprising CdTe and Te, and a composite film comprising a CdTex compound film with an x value larger than 1; and the Te-rich precursor film is reacted with Cd to form a stoichiometric CdTe film on the base.

### CROSS-REFERENCE TO RELATED APPLICATION

This application claims benefit of U.S. Provisional Application No. 61/396,114, filed May 21, 2010, the contents of which are incorporated by reference herein in their entirety for all purposes.

### FIELD OF THE INVENTION

The present invention relates to methods for fabricating thin film Group IIB-VIA compound solar cells, more specifically CdTe radiation detectors and solar cells.

### BACKGROUND

Solar cells and modules are photovoltaic (PV) devices that convert sunlight energy into electrical energy. The most common solar cell material is silicon (Si). However, lower cost PV cells may be fabricated using thin film growth techniques that can deposit solar-cell-quality polycrystalline compound absorber materials on large area substrates using low-cost methods.

Group IIB-VIA compound semiconductors comprising some of the Group IIB (Zn, Cd, Hg) and Group VIA (O, S, Se, Te, Po) materials of the periodic table are excellent absorber materials for thin film solar cell structures. Especially CdTe has proved to be a material that can be used in manufacturing high efficiency solar panels at a manufacturing cost of below $1/W.

FIG. 1A shows a “super-strate” CdTe solar cell structure 10, wherein light enters the active layers of the device through a transparent sheet 11. The transparent sheet 11 serves as the support on which the active layers are deposited.

FIG. 1B depicts a “sub-strate” device structure, wherein light enters the device through a transparent conductive layer deposited over the CdTe absorber which is grown over a substrate.

In fabricating the “super-strate” structure 10 of FIG. 1A, a transparent conductive layer (TCL) 12 is first deposited on the transparent sheet 11. Then a junction partner layer 13 is deposited over the TCL 12. A CdTe absorber film 14 is formed on the junction partner layer 13. Then an ohmic contact layer 15 is deposited on the CdTe absorber film 14, completing the solar cell. As shown by arrows 18 in FIG. 1A, light enters this device through the transparent sheet 11 The transparent sheet 11 may be glass or a material (e.g. a high temperature polymer such as polyimide) that has high optical transmission (such as higher than 80%) in the visible spectra of the sun light. The TCL 12 is usually a transparent conductive oxide (TCO) layer comprising any one of; tin-oxide, cadmium-tin-oxide, indium-tin-oxide, and zinc-oxide which are doped to increase their conductivity. Multi layers of these TCO materials as well as their alloys or mixtures may also be utilized in the TCL 12. The junction partner layer 13 is typically a CdS layer, but may alternately be a compound layer such as a layer of CdZnS, ZnS, ZnSe, ZnSSe, CdZnSe, etc. The ohmic contact 15 is made of a highly conductive metal such as Mo, Ni, Cr, Ti, Al or a doped transparent conductive oxide such as the TCOs mentioned above. The rectifying junction, which is the heart of this device, is located near an interface 19 between the CdTe absorber film 14 and the junction partner layer 13.

In the “sub-strate” structure 17 of FIG. 1B, the ohmic contact layer 15 is first deposited on a sheet substrate 16, and then the CdTe absorber film 14 is formed on the ohmic contact layer 15. This is followed by the deposition of the junction partner layer 13 and the transparent conductive layer (TCL) 12 over the CdTe absorber film 14. As shown by arrows 18 in FIG. 1B, light enters this device through the TCL 12. There may also be finger patterns (not shown) on the TCL 12 to lower the series resistance of the solar cell. The sheet substrate 16 does not have to be transparent in this case. Therefore, the sheet substrate 16 may comprise a sheet or foil of metal, glass or polymeric material.

The CdTe absorber film 14 of FIGS. 1A and 1B may be formed using a variety of methods. For example, U.S. Pat. No. 4,388,483 granted to B. M. Basol et al., describes fabrication of a CdS/CdTe solar cell wherein the thin CdTe film is formed by a cathodic compound electrodeposition technique at low electrolyte temperatures. After electrodeposition the n-type CdTe film is type-converted to p-type through a high temperature annealing step to form the rectifying junction between the converted CdTe film and the underlying CdS layer. The compound electrodeposition or electroplating technique typically uses acidic aqueous electrolytes and forms rectifying junctions after the type-conversion step yielding solar cells and modules with conversion efficiencies exceeding 10% (D. Cunningham et al, “CdTe PV module manufacturing at BP solar”, Progress in Photovoltaics, vol. 10, p. 159 (2002)). However, this electroplating technique is slow, yielding 1-2 micron thick CdTe layers in 2-5 hours depending upon the plating conditions and the size of the substrate. As explained in a review titled “Electrodeposition of Semiconductors” (D. Lincot, Thin Solid Films, vol. 487, p. 40 (2005)), CdTe can be cathodically electrodeposited out of an acidic electrolyte containing Cd and Te, at a potential which is more negative than the Te plating potential but more positive than the Cd plating potential. The reason for this is the fact that the free energy formation of CdTe, which is −98.8 kJ/mol, drives the reaction of the Cd species in the solution with Te, forming CdTe, once Te is electrodeposited on the cathode. Kinetics of this reaction is slow and the Te concentration in the acidic solution is low.

There have been attempts in the literature to accelerate the CdTe electroplating process. For example, C. Lepiller et al. (“Fast electrodeposition route for cadmium telluride solar cells”, Thin Solid Films, vol. 361-362, p. 118 (2000)) studied regimes of the process where the growth rate was 2-7.5 microns/hour. These films yielded only 0.5-6% efficient solar cells, which are far inferior to the 10-12% efficient devices that can be fabricated on films grown by the slow process.

In yet another approach, which is a “two-stage” approach, a CdTe layer may be formed by first depositing a precursor stacked layer comprising a Cd layer and a Te layer on a base, and then by annealing and reacting this precursor stacked layer to form the CdTe compound. As an example of prior art two-stage techniques, U.S. Pat. No. 4,950,615 discloses a method employing electrodeposited Te and Cd stacked layers to form a precursor. In this method, a glass/TCO/CdS structure is used as a base, and a Te layer is electrodeposited on the surface of the CdS film. This is then followed by the electrodeposition of a Cd film on the Te layer forming the stack of glass/TCO/CdS/Te/Cd, wherein the Te/Cd pair constitutes a precursor layer. During the second stage of the process, the stack is heated causing a reaction between the Te and Cd layers, thus forming a CdTe film and at the same time forming a CdTe/CdS rectifying junction between the formed CdTe layer and the underlying CdS layer. The resulting final stack is a super-strate structure of glass/TCO/CdS/CdTe that needs a contact layer to be deposited on the CdTe film to fabricate a solar cell. In this prior art method, the thicknesses of the Cd and Te layers are each about 0.5 microns or thicker, and the process of CdTe formation is solid-state diffusion between the Cd and Te layers. Consequently, the processing times to form CdTe exceeds 30 minutes, even 60 minutes at temperatures of around 500° C. Such slow processing increases cost. Another issue with this technique is the fact that CdS and Te layers are physically in contact within the stack before the heating/reaction step. Therefore, until the CdTe film forms, the CdS layer may chemically interact with the Te layer at high temperature. Such interaction reduces the electronic quality of the CdS/CdTe junction that is formed once the CdTe layer is fully formed.

As the above review demonstrates, there is still a need to develop low cost methods for depositing high quality CdTe layers at high processing rates.

### BRIEF DESCRIPTION OF THE DRAWINGS

FIG. 1A is a cross-sectional view of a prior-art CdTe solar cell with a “super-strate structure”.

FIG. 1B is a cross-sectional view of a prior-art CdTe solar cell with a “sub-strate structure”.

FIG. 2 shows the different electrodeposition process zones with different Te/Cd molar ratios

FIG. 3 shows the process sequence of one preferred embodiment.

FIG. 4 shows a portion of a large base being coated with a film containing Cd and Te by an electrodeposition approach.

FIG. 5A is a view of the large base after the coating process.

FIG. 5B is a cross sectional view of the structure of FIG. 5A taken along the line “E-E”.

### DETAILED DESCRIPTION OF THE PREFERRED EMBODIMENTS

In general, the present invention forms a high quality MTe thin film by a novel approach where M is at least one of Cd, Zn, Hg, Mg and Mn. In one preferred embodiment, a CdTeₓ film, or a composite film comprising (CdTe+Te), or (CdTeₓ+Te) or (CdTeₓ+CdTe) or (CdTeₓ+CdTe+Te) is deposited forming a precursor layer, wherein x is a value larger than 1. The precursor layer is then reacted with Cd species to convert the elemental Te and/or the CdTeₓ phase into CdTe, which is fused with the CdTe material which may already be present in the composite film, to form the high quality CdTe film. In a preferred embodiment the depositions of the precursor layer and the Cd species may be carried out using the electrodeposition techniques.

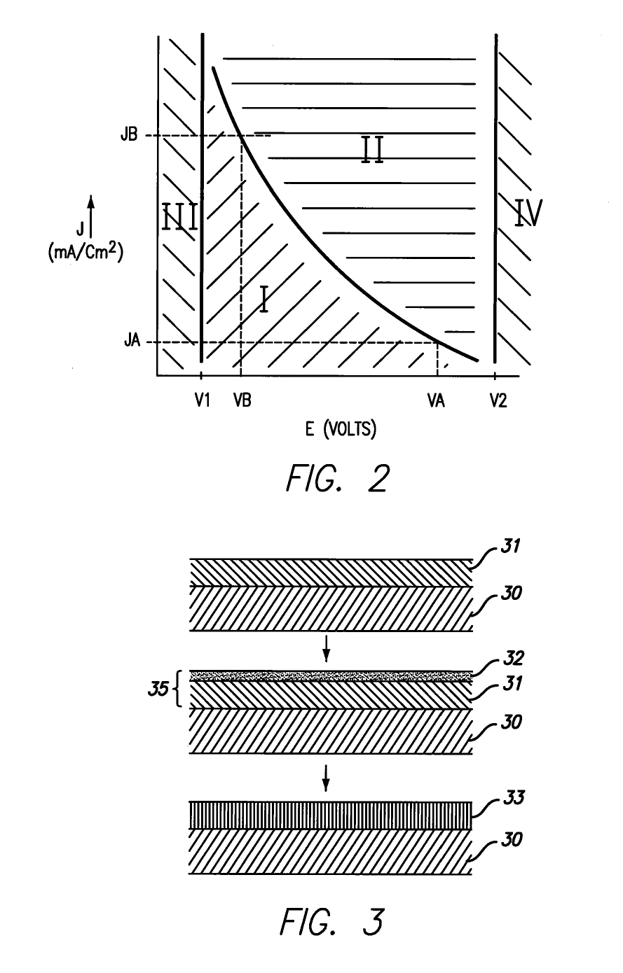

FIG. 2 schematically shows the relationship between the plating potential (E), plating current density (J), and the plated species when a film is electrodeposited out of an acidic plating bath containing Cd and Te species. As can be seen from this figure, there are four different zones or regions in this process. For process conditions that fall within Zone I, the compound CdTe is electroplated on the cathode surface. In Zone II, a deposit comprising the compound CdTe as well as the compound CdTeₓ (x>1) may be electrodeposited with or without elemental Te. Alternately, it is also possible to have the compound CdTeₓ in the form of CdTe₂ in the deposited film in Zone II. Zone III corresponds to electrodeposition potentials that are very close to or more negative than the deposition potential of Cd, which is shown as “V1” in FIG. 2. That means elemental Cd can be electroplated in zone III possibly along with some CdTe phase. Zone IV is close to Te deposition potential, shown as V2, and therefore elemental Te may be electroplated in Zone IV, possibly along with a Te-rich CdTeₓ phase. It should be noted that the values of the deposition potentials V1 and V2 may be about −1.1 V and −0.7V respectively with respect to a Mercurous Sulfate Electrode, respectively.

What FIG. 2 demonstrates is the fact that the voltage range or the process window to electrodeposit stoichiometric CdTe compound with a Te/Cd molar ratio of 1.0 (Zone I) is relatively small and it gets narrower as the current density increases. For example, while at a current density value of “JA”, a stoichiometric CdTe compound film can be electroplated at a deposition voltage range between “VA” and “V1”, whereas at the current density value of “JB”, such a film can only be deposited at a voltage range between “VB” and “V1”. As an example, “JA” may be in the range of 0.05-0.5 mA/cm² while “JB” may be in the range of 0.7-5.0 mA/cm². This means that for electrodepositing on large area substrates, the voltage drop present on the surface of the large substrate between areas near the electrical contacts and areas away from the electrical contacts would not allow use of high current densities if the goal is to electrodeposit a stoichiometric CdTe compound over the whole surface of the substrate. Therefore, to achieve uniformly stoichiometric CdTe over large area, low current densities would be used reducing the throughput of the process.

In one embodiment of the present invention, a precursor layer is deposited on a base. The precursor layer comprises an overall Te-rich composition with a Te/Cd molar ratio of larger than 1.0. The precursor layer may comprise CdTeₓ compound phase where x may preferably be more than one and less than or equal to 2. In its as-deposited form, the Te-rich composition of the precursor layer does not allow it to be used as a solar cell absorber since the extra Te in the layer causes electrical shorting through the layer. Once the precursor layer is obtained, it is reacted with Cd so that excess Te within the precursor layer is converted into CdTe and the overall film becomes a solar-cell-grade CdTe layer, which is a stoichiometric compound with the Te/Cd molar ratio of 1.0.

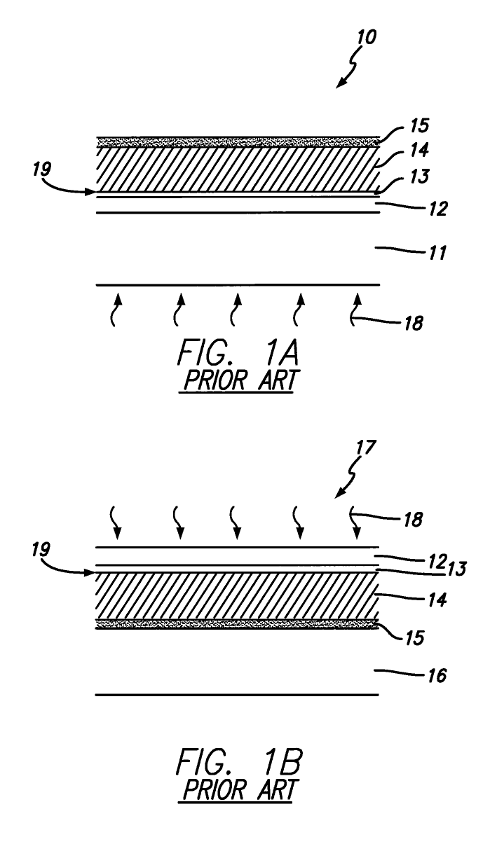

FIG. 3 shows the processing steps of a preferred embodiment of the present invention. First a Te-rich precursor film 31 is deposited on a base 30. The base 30 may be a stack comprising the transparent sheet 11, the transparent conductive layer (TCL) 12, and the junction partner layer 13 shown in FIG. 1A. Alternately, the base 30 may be a stack comprising the sheet substrate 16 and the ohmic contact layer 15 shown in FIG. 1B. The Te-rich precursor film 31 comprises Te and Cd with a Te/Cd molar ratio larger than 1. The Te-rich precursor film 31 may be a composite layer comprising (zCdTe+yTe), in which case the Te/Cd molar ratio in the composite layer can be given by the formula (y+z)/z. Alternately the Te-rich precursor film 31 may be a layer of CdTeₓ compound, where x may preferably be less than or equal to 2 and more than 1. The Te-rich precursor film may be a composite layer of (iCdTeₓ+jTe), in which case the Te/Cd molar ratio in the composite layer can be given by the formula (j+ix)/i. The Te-rich precursor film 31 may be a composite layer comprising CdTeₓ and CdTe. The Te-rich precursor film 31 may also comprise all of CdTe, CdTeₓ and Te phases. However, the Te-rich precursor film does not contain any free metallic Cd.

In a second step of the process, the Te-rich precursor film 31 is reacted with Cd. This can be achieved by various means. In one approach, the temperature of the Te-rich precursor film 31 may be increased to a range of 400-600° C. and exposed to a vapor, containing Cd species. For example, the vapor may comprise elemental Cd or a Cd compound such as CdCl₂. In another approach, which is depicted in FIG. 3, a Cd containing film 32 is first deposited on the Te-rich precursor film 31 forming a secondary precursor layer 35. The secondary precursor layer 35 is then heated up to a temperature range of 400-600° C. to convert it into solar cell grade CdTe compound layer 33, which can be used as an absorber layer in a solar cell structure. It should be noted that the Cd containing film 32 may preferably comprise metallic Cd but may also comprise a Cd salt such as Cd(Y)₂, where Y may be at least one of Cl, Br, and I.

In one preferred embodiment the Te-rich precursor film 31 is deposited by the electrodeposition process, preferably out of an acidic electrolyte containing Cd and Te. Deposition may be carried out at a current density of higher than 1 mA/cm², which yields growth rates higher than 2.5 microns/hr. Considering the fact that about 1.5 micron thick CdTe layer is enough for high efficiency solar cell fabrication, the electrodeposition process time in this approach may be less than 30 minutes, even less than 10 minutes.

As an example, lets consider a Te-rich precursor film to contain CdTe and elemental Te phases. When a Cd layer is deposited on this Te-rich precursor film forming a secondary precursor layer and the reaction is initiated by high temperature processing, the excess Te in the Te-rich precursor film reacts with the Cd, forming CdTe. The CdTe phases which are already present and dispersed throughout the Te-rich precursor film act as nucleation centers during this process, helping and accelerating the formation of the new CdTe phase which fuses with the existing CdTe phase in the Te-rich precursor film. The resulting layer, after reaction, is a high quality CdTe compound layer with well fused grains. The processing time in the present invention is shorter than the prior art approach that forms CdTe by reacting a Te/Cd stack. One reason for the higher throughput of the present method is the fact that the precursor film already contains 30-90% CdTe phase. Therefore, only 10-70% of the material in the Te-rich precursor film participates in the reaction, compared to 100% in the case of the reaction of a Te/Cd stack. Furthermore, while reacting a Te/Cd stack, CdTe first forms at the interface of the Te and Cd films when the temperature is raised. This initially forms a Te/CdTe/Cd stack. For the rest of the Cd and Te material to react, they need to interdiffuse through a CdTe interface which gets thicker in time. The Te-rich precursor film of the present invention, on the other hand, may have the Te, CdTe and CdTeₓ phases dispersed throughout the film, therefore reaction of Cd with the excess Te is easier and faster.

The Cd containing film 32 of FIG. 3 may be deposited by various techniques such as physical vapor deposition, ink deposition by doctor blading, printing, spraying, etc. In a preferred embodiment the Cd containing layer is a substantially pure, elemental Cd layer, and it is deposited by a electrodeposition method out of basic or acidic electrolytes. The heating step of the process can be carried out by rapid thermal processing (RTP), laser annealing or regular furnace annealing for periods ranging from 1-30 minutes.

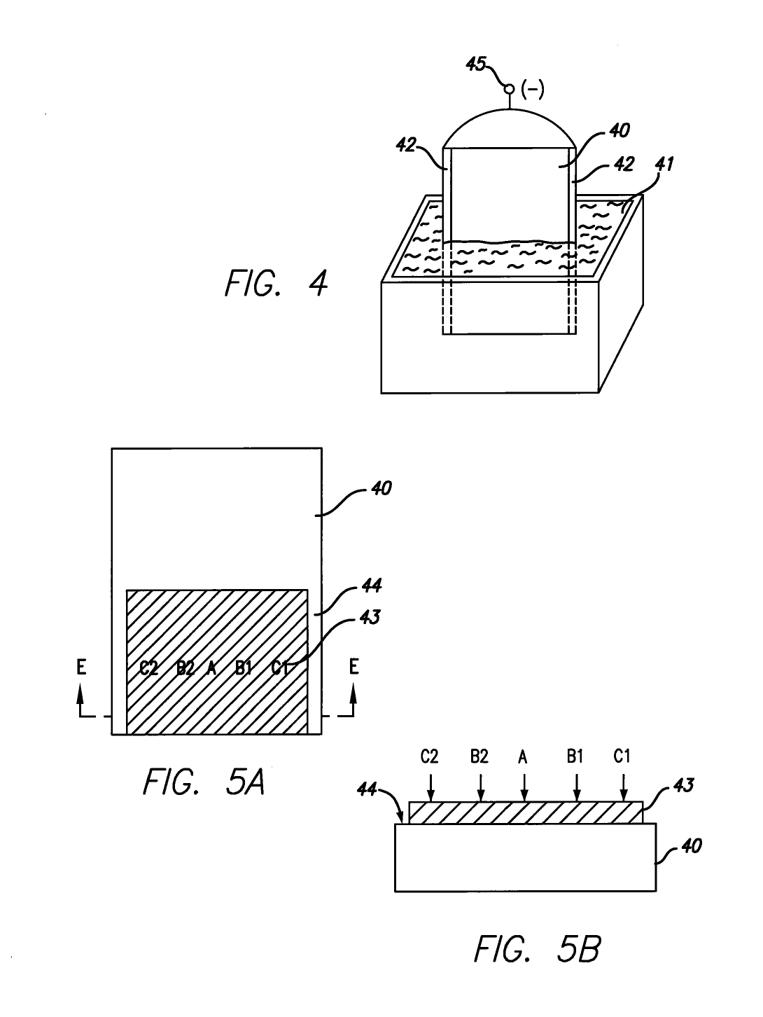

Some of the other advantages of the present invention may be understood by referring to FIGS. 4, 5A and 5B. FIG. 4 schematically shows a large base 40 that is dipped into an electrolyte 41 to receive a Te-rich precursor film coating on part of its surface. There are two contact strips 42 along the two edges of the large base 40, and the two contact strips 42 are connected to a negative (−) terminal 45 of a power source (not shown). There is an anode (not shown) immersed into the electrolyte 41, preferably across from the large base 40, and it is connected to a positive (+) terminal (not shown) of the power source. The electrolyte 41 comprises Cd and Te species and when a voltage is applied between the anode and the two contact strips 42, the Te-rich precursor film is coated on the portion of the large base 40 that is wetted by the electrolyte 41. FIG. 5A shows the large base 40 after the deposition step. As can be seen, the Te-rich precursor film 43 is coated on the lower portion of the large base 40 that was dipped into the electrolyte 41. The areas 44 along the edges are not coated since the contact strips 42 protected these areas from the electrolyte. An exemplary cross sectional view of the “base/Te-rich precursor film” structure taken along the line “E-E” in FIG. 5A is shown in FIG. 5B.

One issue faced in an electrodeposition process is the compositional control of the deposited layer. Normally, the large base 40 may have a short dimension (the horizontal dimension in FIG. 5A) of about 1-4 ft and it may have a surface sheet resistance in the range of 5-20 ohms/square. This means that during plating, there would be a voltage drop between the areas near the contact strips 42, and the areas away from the contact strips 42 and near the middle of the large base 40. Such voltage drop would affect the compositional uniformity of the deposited film (see FIG. 2), the areas near the contact strips being more Cd-rich (or Te poor) compared to areas away from the contact strips. In prior art CdTe plating approaches the current densities would be lowered to below 0.5 mA/cm² to be able to increase the process window for stoichiometric CdTe deposition. For example, a current density value of “JA” would be used (see FIG. 2) so that a voltage range of VA-V1 between the contact strips 42 and the middle of the large base 40 deposits stoichiometric CdTe. In the present approach, the current density would be increased to obtain a Te-rich film and then the stoichiometry of Te/Cd=1 would be achieved by reaction with additional Cd. For example, a current density value of “JB” would be utilized to keep the process in zones I, II and IV. This way a Te-rich precursor film would be obtained. The film may contain pure CdTe phase in portions of the large base 40 which falls (in terms of plating voltage) within Zone I. The film may contain CdTeₓ+CdTe in portions which fall into Zone II, and elemental Te in portions that fall into Zone IV. For the example of FIG. 5A and FIG. 5B, the region A of the Te-rich precursor film 43 would have the highest Te/Cd ratio. The Te/Cd ratio would then get reduced in regions B1 and B2, and further reduced in regions C1 and C2. If the Te-rich precursor film 43 was annealed by itself, it would not yield any solar cells, especially near the regions, A, B1 and B2 since the Te/Cd ratio in these regions would be larger than 1.0. When this film is annealed in Cd containing vapor or when a Cd layer is deposited over the Te-rich precursor film 43 forming a secondary precursor layer, which is then annealed, the originally non uniform composition throughout the plated area would be automatically adjusted to the desired value of Te/Cd=1. This is because the different areas in the Te-rich precursor film with different Te/Cd ratios, would react with just enough Cd to bring their Te/Cd ratio to 1. Any excess Cd at that region would simply evaporate away at elevated temperature since the vapor pressure of Cd is high even at atmospheric pressure. Embodiments of the present invention thus allow for fast electrodeposition process to be employed for processing large area bases. Embodiments of the invention further allow automatic adjustment of the stoichiometry of the compound layer by the end of the process even if the initially electrodeposited precursor layer has a highly non-uniform composition due to the use of high current densities which cause excessive voltage drop on the surface of the base. It should be noted the thickness of the Te-rich precursor film may be in the range of 0.3-2 microns, preferably in the range of 0.5-1.5 microns and the thickness of the Cd layer may be in the range of 0.1-1 microns, preferably in the range of 0.2-0.5 microns.

It should be noted that the composition of the electrodeposited film can be further controlled through its thickness by controlling the deposition potential applied from the power supply. For example, when a deposition on a large base is initiated, a low current density may be first selected to electroplate a stoichiometric CdTe sub-layer on the base to a predetermined thickness, which may be in the range of 0.05-0.2 microns. The current density may then be increased to electrodeposit a Te-rich layer on the CdTe sub-layer at a higher current density. After reaction with Cd, the CdTe sub-layer and the Te-rich layer that is reacted with Cd fuse together and form a high quality CdTe compound layer with a thickness in the range of 1-3 microns.

The techniques described are also applicable to the formation of absorber layers that include other elements. For example, films comprising alloys of CdTe with materials such as Zn, Hg, Mn and Mg may also be formed by including these elements in the Te-rich precursor film in addition to the Cd and Te species. In this case the absorber layer may be represented by the chemical formula “MTe” where M comprises Cd and may optionally additionally comprise at least one of Zn, Hg, Mn and Mg.

Although the present invention is described with respect to certain preferred embodiments, modifications thereto will be apparent to those skilled in the art.

What is claimed:

1. A method of forming a telluride film on a base comprising;
depositing a Te-rich precursor film on the base; and
reacting the Te-rich precursor film with M,
wherein:
M comprises Cd; and
wherein:
the Te-rich precursor film is one of a MTeₓ compound film with an x value larger than 1, a composite film comprising MTe and Te, and a composite film comprising a MTeₓ compound film with an x value larger than 1.

2. The method in claim 1, wherein M also comprises at least one of Zn, Hg, Mg and Mn.

3. The method in claim 1 wherein the step of reacting comprises heating the Te-rich precursor film to a temperature range and providing a Cd-containing vapor to the surface of the Te-rich precursor film.

4. The method in claim 3 wherein the temperature range is 400-600° C.

5. The method in claim 1 wherein the step of reacting comprises laying down a layer of Cd over the Te-rich precursor film forming a precursor stack and heating the precursor stack to a temperature.

6. The method in claim 5 wherein the temperature is in the range of 400-600° C.

7. The method in claim 1 wherein the step of depositing is carried out by an electrodeposition technique.

8. The method in claim 4 wherein the step of depositing is carried out by an electrodeposition technique.

9. The method in claim 5 wherein the step of depositing is carried out by an electrodeposition technique.

10. The method in claim 6 wherein the step of depositing is carried out by an electrodeposition technique.

11. The method in claim 10 wherein the layer of Cd is laid down by an electrodeposition method.

12. The method of any one of claims 7-10, wherein the electrodeposition technique is carried out, at least in part, with a current density in the range of 0.7-5.0 mA/cm².

13. The method of any one of claim 7-10, wherein the electrodeposition technique is carried out with a current density and plating potential such that substantially no free metallic Cd is deposited and is carried out, at least in part, with a current density in the range of 0.7-5.0 mA/cm².

14. The method of any one of claim 7-10, wherein the electrodeposition technique is carried out, at least in part, with a current density in the range of 0.7-5.0 mA/cm² and with a plating potential between the deposition potential of Cd and the deposition potential of Te.

15. A solar cell having a telluride film made in accordance with claim 1.
